(19) United States
(12) Patent Application Publication
(10) Pub. No.: US 2021/0384217 A1
(43) Pub. Date: Dec. 9, 2021

(54) SEMICONDUCTOR DEVICE

(71) Applicant: Samsung Electronics Co., Ltd., Suwon-si (KR)

(72) Inventors: Hauk Han, Hwaseong-si (KR); Taeyong Kim, Suwon-si (KR); Keun Lee, Seongnam-si (KR); Jeonggil Lee, Hwaseong-si (KR); Taisoo Lim, Seoul (KR); Hanmei Choi, Seoul (KR)

(21) Appl. No.: 17/151,383

(22) Filed: Jan. 18, 2021

(30) Foreign Application Priority Data
Jun. 5, 2020 (KR) 10-2020-0068105

(51) Int. Cl. H01L 27/11582; H01L 27/11565; H01L 27/11519; H01L 27/11556

(52) U.S. Cl. CPC H01L 27/11582; H01L 27/11556; H01L 27/11519; H01L 27/11565

(57) ABSTRACT

A semiconductor device includes gate electrodes stacked and spaced apart from each other in a first direction perpendicular to an upper surface of a substrate; interlayer insulating layers alternately stacked with the gate electrodes on the substrate; channel structures extending through the gate electrodes; and a separation region extending through the gate electrodes in the first direction and extending in a second direction perpendicular to the first direction, wherein each of the gate electrodes comprises a first conductive layer and a second conductive layer sequentially stacked, the second conductive layer including a metal nitride, and wherein the first conductive layer and the second conductive layer are each in physical contact with the separation region.

### CROSS-REFERENCE TO RELATED APPLICATION(S)

This application claims benefit of priority to Korean Patent Application No. 10-2020-0068105 filed on Jun. 5, 2020 in the Korean Intellectual Property Office, the disclosure of which is incorporated herein by reference in its entirety.

### BACKGROUND

The present inventive concept relates to a semiconductor device, and, more particularly, to a semiconductor device including gate electrodes including sequentially stacked conductive layers.

Because semiconductor devices may require a high-capacity data processing capability even while volumes thereof are getting smaller, it may be necessary to increase a degree of integration of the semiconductor elements constituting such semiconductor devices. Accordingly, as one method for improving the degree of integration of a semiconductor device, a semiconductor device having a vertical transistor structure, instead of a conventional planar transistor structure, has been proposed.

### SUMMARY

An aspect of the present inventive concept is to provide a semiconductor device having improved reliability.

According to an aspect of the present inventive concept, a semiconductor device includes gate electrodes stacked gate electrodes stacked and spaced apart from each other in a first direction perpendicular to an upper surface of a substrate; interlayer insulating layers alternately stacked with the gate electrodes on the substrate; channel structures extending through the gate electrodes; and a separation region extending through the gate electrodes in the first direction and extending in a second direction perpendicular to the first direction, wherein each of the gate electrodes comprises a first conductive layer and a second conductive layer sequentially stacked , the second conductive layer including a metal nitride, and wherein the first conductive layer and the second conductive layer are each in physical contact with the separation region.

According to an aspect of the present inventive concept, a semiconductor device includes gate electrodes stacked gate electrodes stacked and spaced apart from each other in a first direction perpendicular to an upper surface of a substrate; interlayer insulating layers alternately stacked with the gate electrodes on the substrate; channel structures extending through the gate electrodes; and a separation region extending through the gate electrodes in the first direction and extending in a second direction perpendicular to the first direction, wherein each of the gate electrodes comprises a first conductive layer and a second conductive layer sequentially stacked, and wherein a thickness of the second conductive layer in the first direction is in a range of about 1% to about 30% of an interval between adjacent ones of the interlayer insulating layers in the first direction.

According to an aspect of the present inventive concept, a semiconductor device includes gate electrodes stacked gate electrodes stacked and spaced apart from each other in a first direction perpendicular to an upper surface of a substrate; interlayer insulating layers alternately stacked with the gate electrodes on the substrate; channel structures extending through the gate electrodes; and a separation region extending through the gate electrodes in the first direction and extending in a second direction perpendicular to the first direction, wherein each of the gate electrodes comprises a first conductive layer and a second conductive layer on the first conductive layer, the gate electrodes being arranged on an internal surface bordered by adjacent ones of the interlayer insulating layers and one of the channel structures, wherein the first conductive layer and the second conductive layer are each in physical contact with the separation region, and wherein the first conductive layer comprises a first material having a first resistance, and the second conductive layer comprises a second material having a second resistance, greater than the first resistance, wherein the second material comprises nitrogen (N).

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic plan view of a portion of a semiconductor device according to example embodiments of the inventive concept.

FIG. 2A is a schematic cross-sectional view of a portion of a semiconductor device according to example embodiments of the inventive concept.

FIG. 2B is a partially enlarged view of a semiconductor device according to example embodiments of the inventive concept.

FIGS. 3A and 3B are schematic plan views of a portion of a semiconductor device according to example embodiments of the inventive concept.

FIGS. 4A to 4E are partially enlarged views of a semiconductor device according to example embodiments of the inventive concept.

FIG. 5 is a schematic cross-sectional view of a semiconductor device according to example embodiments of the inventive concept.

FIG. 6 is a schematic cross-sectional view of a semiconductor device according to example embodiments of the inventive concept.

FIG. 7 is a schematic cross-sectional view of a semiconductor device according to example embodiments of the inventive concept.

FIGS. 8A to 8G are schematic cross-sectional views illustrating a method of manufacturing a semiconductor device according to example embodiments of the inventive concept.

### DETAILED DESCRIPTION

Hereinafter, example embodiments of the present inventive concept will be described with reference to the accompanying drawings. The same reference numerals are used for the same elements in the drawings, and redundant descriptions thereof will be omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It is noted that aspects described with respect to one embodiment may be incorporated in different embodiments although not specifically described relative thereto. That is, all embodiments and/or features of any embodiments can be combined in any way and/or combination.

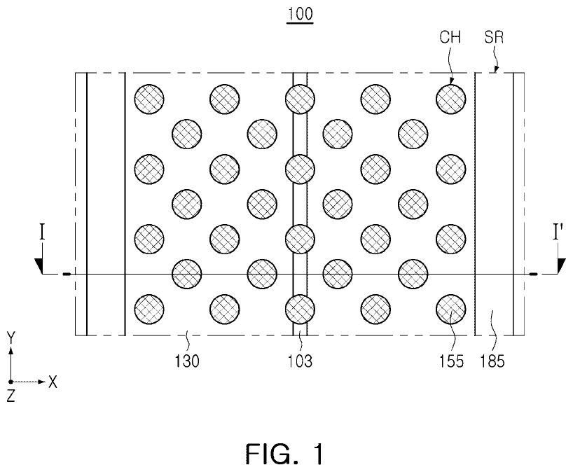

FIG. 1 is a schematic plan view of a portion of a semiconductor device according to example embodiments of the inventive concept.

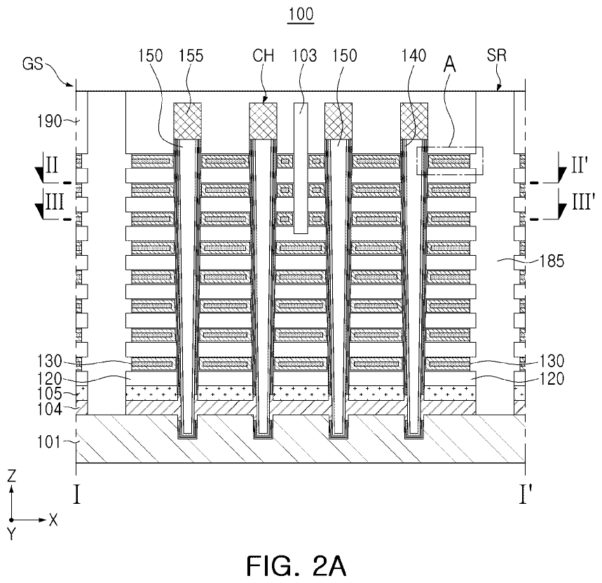

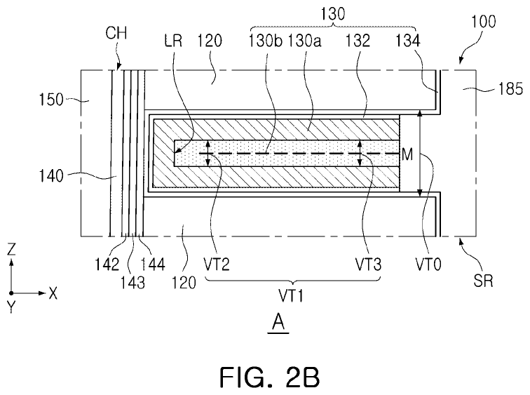

FIG. 2A is a schematic cross-sectional view of a portion of a semiconductor device according to example embodiments of the inventive concept. FIG. 2A is a cross-sectional view of the semiconductor device of FIG. 1 taken along line I-I′. For convenience of description, only major components of a semiconductor device will be illustrated in FIGS. 1 and 2A.

FIG. 2B is a partially enlarged view of a semiconductor device according to example embodiments of the inventive concept. FIG. 2B is an enlarged view of portion A of FIG. 2A.

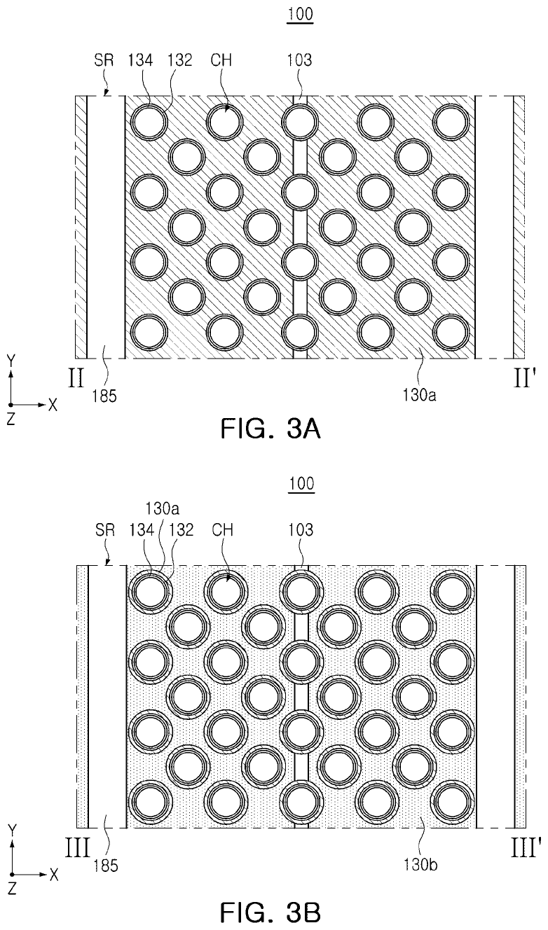

FIGS. 3A and 3B are schematic plan views of a portion of a semiconductor device according to example embodiments of the inventive concept. FIG. 3A is a plan view of the semiconductor device of FIG. 2A taken along line and FIG. 3B is a plan view of the semiconductor device of FIG. 2A taken along line For example, FIG. 3A is a plan view in which an upper surface of a first conductive layer 130a is cut in a direction, parallel to an upper surface of the semiconductor substrate, and FIG. 3B is a plan view in which a center of a second conductive layer 130b is cut in a direction, parallel to the upper surface of the semiconductor substrate.

Referring to FIGS. 1 to 3B, a semiconductor device 100 may include a substrate 101, channel structures CH extending in a direction, perpendicular to an upper surface of the substrate 101, and having a channel layer 140 disposed therein, a plurality of interlayer insulating layers 120 stacked along external side walls of the channel structures CH, a plurality of gate electrodes 130 alternately stacked with the interlayer insulating layers 120 and including a first conductive layer 130a and a second conductive layer 130b, and separation regions SR extending through a stack structure GS of the interlayer insulating layers 120 and the gate electrodes 130 in a Z direction and extending in a Y direction. In addition, the semiconductor device 100 may further include first and second conductive patterns 104 and 105, arranged between the substrate 101 and the interlayer insulating layers 120. The separation region SR may include separation insulating layers 185, and the separation insulating layers 185 may include an insulating material, for example, silicon oxide. In example embodiments, the first and second conductive patterns 104 and 105 may be omitted. In these embodiments, the channel structures CH may include an epitaxial layer disposed below the channel layer 140, i.e., between the channel layer 140 and the substrate 101, and the separation regions SR may include a conductive material, and an insulating material that is configured to electrically insulate the conductive material from the stack structure GS.

In the semiconductor device 100, a memory cell string may be formed around the channel layer 140, and a plurality of memory cell strings may be arranged in columns and rows in X and Y directions, respectively.

The substrate 101 may have an upper surface extending in the X and Y directions. The substrate 101 may include a semiconductor material, such as a group IV semiconductor, a group III-V compound semiconductor, and/or a group II-VI compound semiconductor. For example, the group IV semiconductor may include silicon, germanium, and/or silicon-germanium. The substrate 101 may be provided as a bulk wafer, an epitaxial layer, a silicon-on-insulator (SOI) layer, a semiconductor-on-insulator (SeOI) layer, or the like.

The gate electrodes 130 may be disposed to be spaced apart from each other in a direction, perpendicular to an upper surface of the substrate 101, along a side surface of each of the channel structures CH. Each of the gate electrodes 130 may include ground select electrodes, cell electrodes, and string select electrodes, constituting a gate electrode of a ground select transistor, gate electrodes of a plurality of memory cells, and a gate electrode of a string select transistor, respectively. In example embodiments, the gate electrodes 130 may further include erasing electrodes located in an upper portion and/or a lower portion of the gate electrodes 130 and forming a gate electrode of an erase transistor. In this case, among a plurality of lower gate electrodes, a gate electrode located on a gate electrode of an erase transistor used for an erasing operation may be a ground select electrode of the ground select transistor, and at least a portion of a plurality of intermediate gate electrodes may be word lines of a vertical NAND flash memory element, constituting memory cells. Among a plurality of upper gate electrodes, one or a plurality of gate electrodes located below the gate electrode of the erase transistor, i.e., closer to the substrate 101, may be one or a plurality of string select electrodes.

The gate electrodes 130 may extend to form a ground select line, word lines, and a string select line, and the word lines may be connected in common in adjacent memory cell strings of a predetermined unit and may be arranged in the X and Y directions. String select electrodes constituting the string select line may be separated from each other at predetermined intervals in the X direction by an upper insulating layer 103. The number of string select electrodes separated by the upper insulating layer 103 is not limited to those illustrated herein.

In accordance with difference embodiments of the inventive concept, the string select electrodes and the ground select electrodes may be one or two or more, respectively, and may have the same or a different structure as the cell electrodes. A portion of the gate electrodes 130, for example, the gate electrodes 130, adjacent to the string select electrodes or the ground select electrodes, may be dummy gate electrodes.

The gate electrode 130, provided as a single layer, may include the first conductive layer 130a and the second conductive layer 130b disposed on the first conductive layer 130a, and arranged on an internal surface at least partially surrounded or bordered by the interlayer insulating layers 120, adjacent to each other in the vertical direction, and the channel structure CH. Each of the first conductive layer 130a and the second conductive layer 130b may be in physical contact with the separation region SR.

The first conductive layer 130a and the second conductive layer 130b may be sequentially stacked on the interlayer insulating layer 120. The first conductive layer 130a may be on and at least partially cover an upper surface, a lower surface, and one side surface of the second conductive layer 130b, and the other side surface of the second conductive layer 130b may be in physical contact with the separation region SR. The first conductive layer 130a may be disposed to have a lateral recess region LR recessed toward the channel structure CH.

The second conductive layer 130b may be disposed to be in and at least partially fill the recess region LR on an internal surface of the first conductive layer 130a between the interlayer insulating layers 120 adjacent to each other. The second conductive layer 130b may be deposited and formed along the surface of the first conductive layer 130a, respectively, below and above an interface M illustrated by a dashed line in FIG. 2B, and the layers above and below the dashed line of FIG. 2B may join each other at the interface M without leaving an empty space or void. When a material of the second conductive layer 130b is crystalline, the second conductive layer 130b formed below and above the interface M and abutted by a structure in which a boundary of a grain boundary is formed along the interface M may be confirmed. According to some embodiments, the interface M may not be recognized or the second conductive layer 130b may be formed without the interface M. In an embodiment, the second conductive layer 130b may be disposed in a central portion between the interlayer insulating layers 120 adjacent to each other in the vertical direction.

As illustrated in FIGS. 3A and 3B, the first conductive layer 130a and the second conductive layer 130b may be configured to have an external surface physically contacting the separation region SR, and surround or border the channel structures CH around the channel structures CH. The first conductive layer 130a may be disposed to surround or border a first blocking layer 134 around the channel structures CH. The second conductive layer 130b may be disposed to surround or border the first conductive layer 130a around the channel structures CH.

The second conductive layer 130b may have a first thickness VT1 that may be an average thickness in the Z direction. The second conductive layer 130b may have a second thickness VT2 in a region distant from the separation region SR, and a third thickness VT3 in a region adjacent to the separation region SR, according to a shape of the first conductive layer 130a. The second thickness VT2 and the third thickness VT3 may be substantially the same. For example, the second conductive layer 130b may have a substantially uniform thickness across its length in the x-direction. In addition, the first conductive layer 130a may have a substantially uniform thickness between the interlayer insulating layer 120 and the second conductive layer 130b, but is not limited thereto, and according to some embodiments, a thickness (VT1) in the Z direction may have a shape increasing with proximity to the separation region SR.

The first conductive layer 130a and the second conductive layer 130b may include the same or different materials. The first conductive layer 130a may include a metal material having a relatively low resistance, for example, one or more of tungsten (W), molybdenum (Mo), copper (Cu), or the like. For example, the first conductive layer 130a may have a first resistance, and the second conductive layer 130b may have a second resistance, greater than the first resistance. The second conductive layer 130b may include a metal or metal nitride that may at least partially fill a space on the internal surface of the first conductive layer 130a between the interlayer insulating layers 120 adjacent to each other. For example, the second conductive layer 130b may include one or more of titanium (Ti), titanium nitride, tantalum (Ta), tantalum nitride, tungsten nitride, or the like. In example embodiments, the second conductive layer 130b may comprise nitrogen (N).

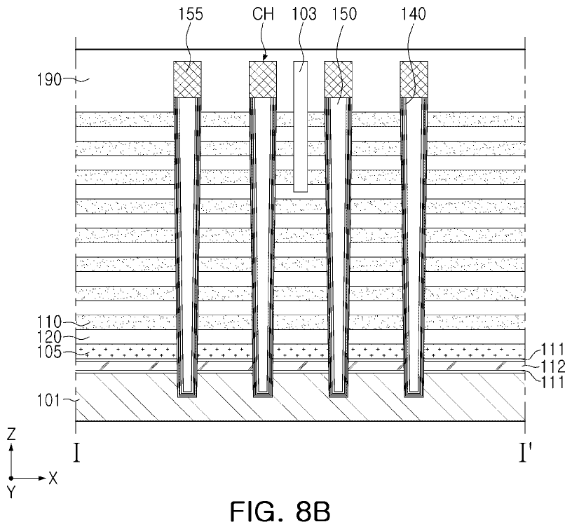

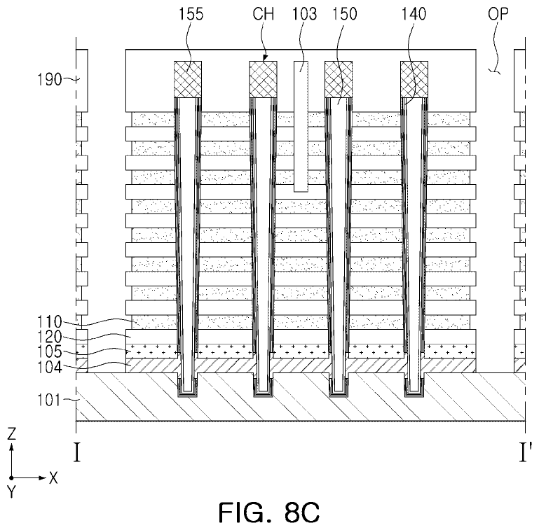

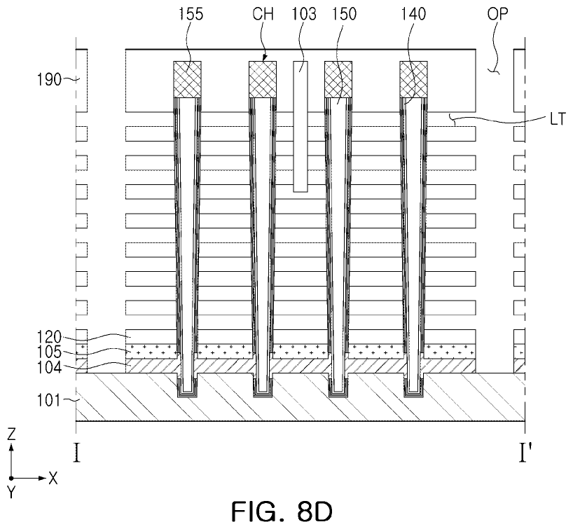

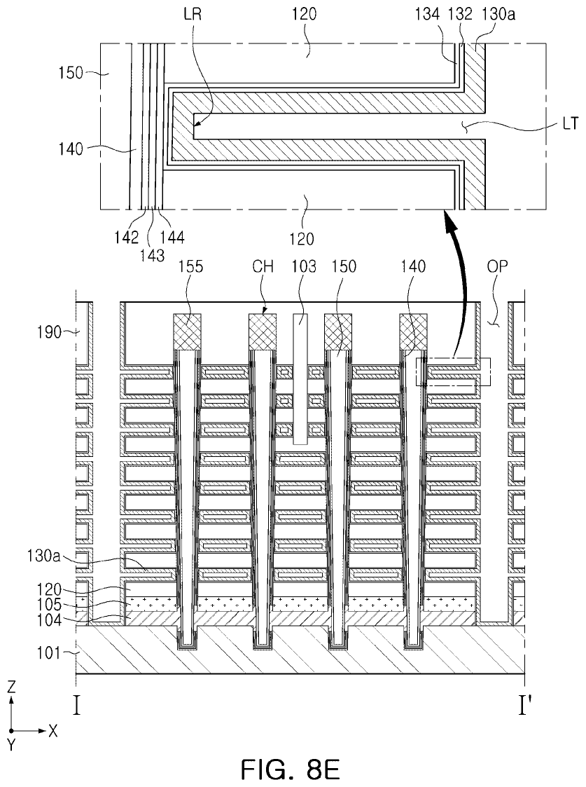

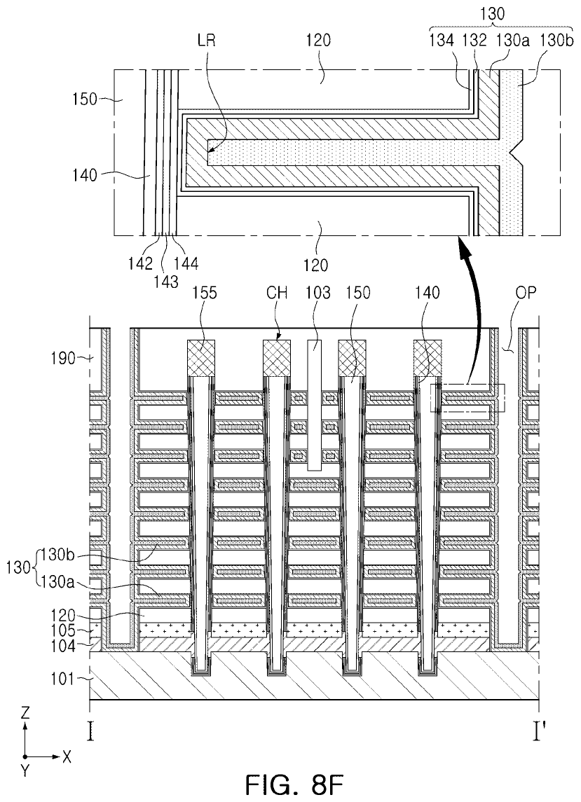

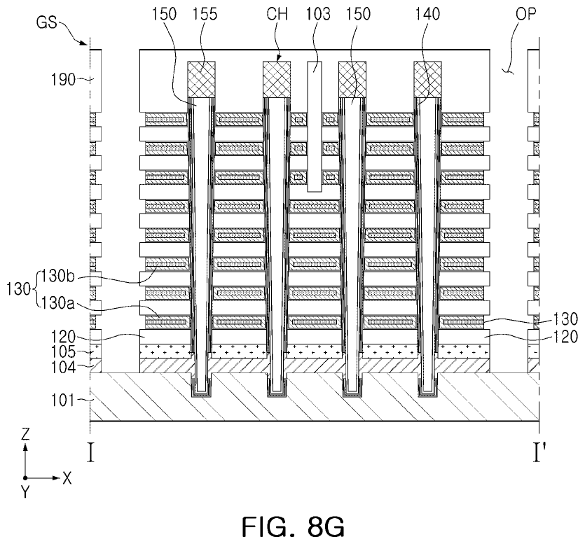

When the space on the internal surface of the first conductive layer 130a includes the second conductive layer 130b between the interlayer insulating layers 120 adjacent to each other in the vertical direction, a slit may not be formed in the first conductive layer 130a. Therefore, because it may be possible to prevent or reduce the likelihood of the first conductive layer 130a from being etched by etching gases or deposition gases during an etching process to be described below with reference to FIG. 8G, the interlayer insulating layers 120 and the gate electrodes 130 may have a stable structure, and deterioration of electrical properties of the semiconductor device may be reduced or prevented.

The first thickness VT1 of the second conductive layer 130b in the Z direction may be in a range of about 1% to about 30% of an interval VTO between adjacent interlayer insulating layers 120. In an embodiment, the first thickness VT1 may be in a range of about 10% to about 20% of the interval VTO between adjacent interlayer insulating layers 120. For example, the first thickness VT1 may be in a range of about 0.5 nm to about 8 nm. In an embodiment, the first thickness VT1 may be in a range of about 1 nm to about 5 nm. When the first thickness VT1 of the second conductive layer 130b is less than the value in the above range, it may be difficult to completely fill the space on the internal surface of the first conductive layer 130a. When the first thickness VT1 of the second conductive layer 130b is greater than the value in the above range, as a thickness of the first conductive layer 130a decreases, resistances of the gate electrodes may increase relatively, which may result in a deterioration of the electrical properties of the semiconductor device.

In example embodiments, the gate electrodes 130 may further include a barrier metal layer 132 and a first blocking layer 134. The first blocking layer 134 and the barrier metal layer 132 may be interposed between the interlayer insulating layer 120 and the first conductive layer 130a, and between the side wall of the channel structure CH and the first conductive layer 130a. In addition, the barrier metal layer 132 may be in physical contact with the separation region SR through a side surface of the barrier metal layer 132. The barrier metal layer 132 may include, for example, one or more of titanium (Ti), titanium nitride, tantalum (Ta), or tantalum nitride.

The first blocking layer 134 may extend along the interlayer insulating layer 120 and may be disposed between the interlayer insulating layer 120 and the barrier metal layer 132. The first blocking layer 134 may include silicon oxide (SiO₂), silicon nitride (Si₃N₄), silicon oxynitride (SiON), a high-k material, or a combination thereof. In some embodiments, the high-k material refers to a dielectric material having a higher dielectric constant than that of silicon oxide (SiO₂). The high-k material may include, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), or a combination thereof. According to some embodiments, the first blocking layer 134 may be omitted.

The interlayer insulating layers 120 may be disposed between the gate electrodes 130. Like the gate electrodes 130, the interlayer insulating layers 120 may be spaced apart from each other in a direction perpendicular to the upper surface of the substrate 101 and may be disposed to extend in the X direction. The interlayer insulating layers 120 may include an insulating material, such as silicon oxide and/or silicon nitride. Side surfaces of the interlayer insulating layers 120 may have a structure protruding from side surfaces of the gate electrodes 130 toward the separation region SR. In an example embodiment, the side surfaces of the interlayer insulating layers 120 may be coplanar with the side surfaces of the gate electrodes 130.

The channel structures CH may be arranged to be spaced apart from each other in rows and columns on the substrate 101. The channel structures CH may be disposed in a grid form or may be disposed in a zigzag form in one direction. The channel structures CH may have a side surface perpendicular to the upper surface of the substrate 101, or may have an inclined side surface that becomes narrower with increasing proximity to the substrate 101 based on an aspect ratio.

In the channel structures CH, the channel layer 140 may be formed in an annular shape surrounding or bordering the channel insulating layer 150 therein. According to an embodiment, the channel layer 140 may have a column shape, such as a cylinder or a prismatic column without the channel insulating layer 150. The channel layer 140 may be directly connected to the substrate 101 in a lower portion of the channel layer 140. The channel layer 140 may include a semiconductor material, such as polycrystalline silicon or monocrystalline silicon, and the semiconductor material may be an undoped material or a material including p-type or n-type impurities. The channel structures CH disposed in a straight line in the X direction may be respectively connected to different bit lines by arranging an upper wiring structure connected to a channel pad 155. In addition, a portion of the channel structures CH may be dummy channels that may not be connected to the bit lines.

As illustrated in FIG. 2B, each of the channel structures CH may include a tunneling layer 142, a charge storage layer 143, and a second blocking layer 144, sequentially formed on the channel layer 140. Relative thicknesses of the tunneling layer 142, the charge storage layer 143, and the second blocking layer 144 are not limited to those illustrated in the drawings and may vary in various embodiments.

The tunneling layer 142 may tunnel charges to the charge storage layer 143 using an F-N tunneling method. The tunneling layer 142 may include, for example, silicon oxide (SiO₂), silicon nitride (Si₃N₄), silicon oxynitride (SiON), or a combination thereof. The charge storage layer 143 may be a charge trap layer and may be made of silicon nitride. The second blocking layer 144 may include silicon oxide (SiO₂), silicon nitride (Si₃N₄), silicon oxynitride (SiON), a high-k material, or a combination thereof.

In the channel structures CH, the tunneling layer 142, the charge storage layer 143, and the second blocking layer 144 may be arranged to extend into the substrate 101. The tunneling layer 142, the charge storage layer 143, and the second blocking layer 144 may be partially removed from lower ends of the channel structures CH, respectively, and in regions from which the tunneling layer 142, the charge storage layer 143, and the second blocking layer 144 are removed, the channel layer 140 may be connected to the first conductive pattern 104.

The channel pad 155 may be disposed to be on and at least partially cover an upper surface of the channel insulating layer 150 and be electrically connected to the channel layer 140. The channel pad 155 may include, for example, doped polycrystalline silicon.

The first and second conductive patterns 104 and 105 may be stacked and arranged on the upper surface of the substrate 101. At least portions of the first and second conductive patterns 104 and 105 may function as a common source line of the semiconductor device 100. The first conductive pattern 104 may be directly connected to the channel layer 140 around the channel structures CH. The first and second conductive patterns 104 and 105 may include a semiconductor material, for example, polycrystalline silicon. In such embodiments, the first conductive pattern 104 may be at least a doped layer, and the second conductive pattern 105 may be a doped layer or a layer including impurities diffused from the first conductive pattern 104.

A cell region insulating layer 190 may be disposed on the stack structure GS of the gate electrodes 130, and may include an insulating material, such as silicon oxide, silicon nitride, or the like.

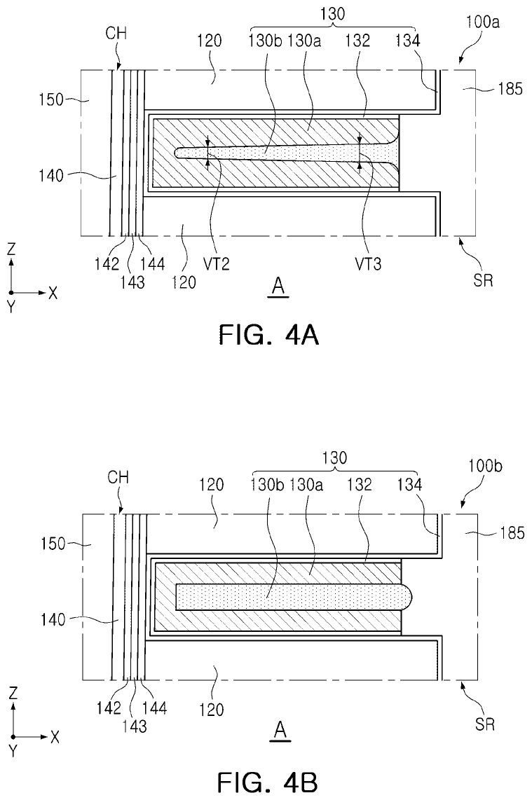

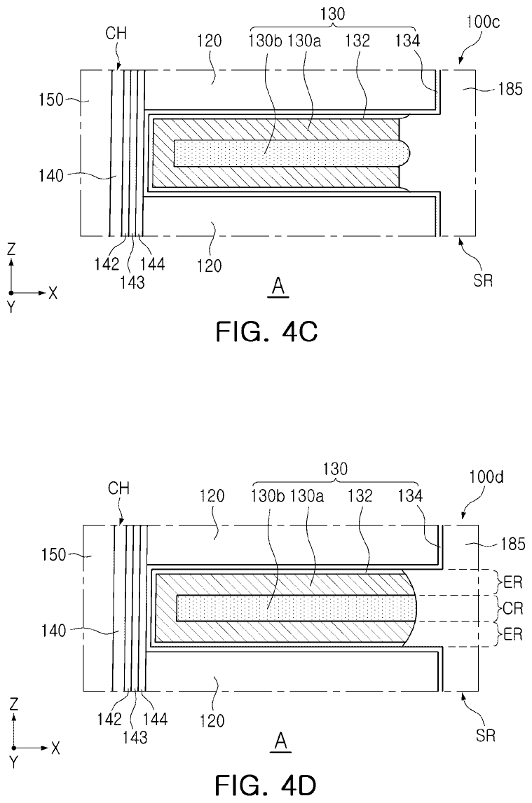

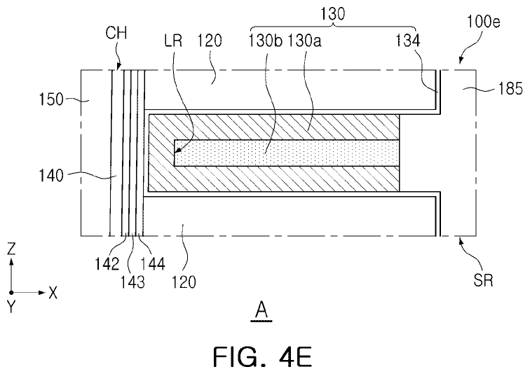

FIGS. 4A to 4E are partially enlarged views of a semiconductor device according to example embodiments of the inventive concept. FIGS. 4A to 4E are enlarged views of a portion of the semiconductor device corresponding to portion A of FIG. 2A.

Referring to FIG. 4A, in a semiconductor device 100a, according to a shape of the first conductive layer 130a, a second conductive layer 130b may have a second thickness VT2 in a region more distant from a separation region SR, and a third thickness VT3 in a region adjacent to the separation region SR, and the second thickness VT2 and the third thickness VT3 may not be uniform. A thickness of the second conductive layer 130b may increase with increasing proximity to the separation region SR. An increase in thickness may not be constant. According to some embodiments, the second conductive layer 130b may have a shape that gradually increases in thickness with increasing proximity to the separation region SR. Even in these embodiments, the first conductive layer 130a and the second conductive layer 130b may each be in physical contact with the separation region SR.

Referring to FIG. 4B, in a semiconductor device 100b, because a first conductive layer 130a and a second conductive layer 130b may have a difference in etch selectivity according to an etching condition, the second conductive layer 130b may have a shape further protruding toward the separation region SR as compared to the first conductive layer 130a. In such embodiments, the second conductive layer 130b of a central region in the z direction may have a relatively long protruding length in the X direction, but embodiments of the inventive concept are not limited thereto.

Referring to FIG. 4C, in a semiconductor device 100c, a barrier metal layer 132 may further protrude toward a separation region SR, together with a second conductive layer 130b, as compared to a first conductive layer 130a. In such embodiments, the barrier metal layer 132 may include a material having the same etching ratio as or an etching ratio similar to the second conductive layer 130b under a specific etching condition. The barrier metal layer 132 may include, for example, one or more of titanium (Ti), titanium nitride, tantalum (Ta), or tantalum nitride.

Referring to FIG. 4D, in a semiconductor device 100d, each gate electrode 130 may include a central portion CR disposed around a center between interlayer insulating layers 120 adjacent to each other in the vertical direction, and an edge portion ER closer to interlayer insulating layer 120, as compared to the central portion CR. A length of the central portion CR in the X direction may be longer than a length of the edge portion ER in the X direction. A second conductive layer 130b may be disposed in the central portion CR of each of the gate electrodes 130, and a first conductive layer 130a may be disposed in the edge portion ER of each of the gate electrodes 130. One surface of each of the gate electrodes 130 physically contacting the separation region SR may be on a straight line or a curved line, and in the example of the curved line, curvature may not be constant.

Referring to FIG. 4E, unlike the semiconductor device 100, a barrier metal layer 132 may be omitted from a semiconductor device 100e. Therefore, in a deposition process described below with reference to FIG. 8E, an operation of depositing the barrier metal layer 132 may be omitted.

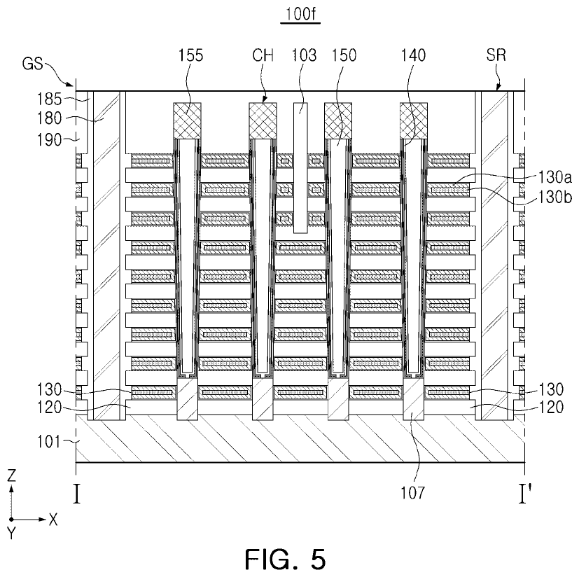

FIG. 5 is a schematic cross-sectional view of a semiconductor device according to example embodiments of the inventive concept.

Referring to FIG. 5, unlike the semiconductor device 100 of FIG. 2A, in a semiconductor device 100f, channel structures CH may not include first and second conductive patterns 104 and 105, and an epitaxial layer 107 disposed below channel layers 140 may be further included. Also, in addition to separation insulating layers 185 disposed in separation regions SR, source conductive layers 180 may be further included.

The channel layer 140 may be connected to the epitaxial layer 107 in a lower portion of the channel structure CH. The epitaxial layer 107 may be disposed on a substrate 101 and on a lower end of the channel structure CH and may be disposed on a side surface of at least one gate electrode 130. The epitaxial layer 107 may be disposed in a recessed region of the substrate 101. An upper surface of the epitaxial layer 107 may be higher than an upper surface of a lowermost gate electrode 130 and may be lower than a lower surface of a gate electrode 130, disposed above the lowermost gate electrode 130, as shown in the cross-sectional view of FIG. 5, but embodiments are not limited to those illustrated herein.

The source conductive layer 180 may be electrically insulated from the gate electrodes 130 by the separation insulating layer 185. Therefore, stack structures GS of the gate electrodes 130 may be separated from each other in the X direction, with the source conductive layer 180 interposed therebetween. The source conductive layer 180 may be disposed in a line shape extending in the Y direction and may correspond to a common source line of the semiconductor device 100f. The source conductive layer 180 may be arranged one by one for every 4 to 8 columns of the channel layer 140 in the X direction, for example, but embodiments are not limited thereto. The separation insulating layer 185 may be disposed to partially extend onto and protrude through interlayer insulating layers 120 to physically contact side surfaces of the gate electrodes 130. The source conductive layer 180 may include a conductive material, such as polycrystalline silicon, metal, or the like, and the separation insulating layer 185 may include an insulating material, such as silicon oxide, silicon nitride, or the like.

A shape of the common source line may be used in the embodiments of FIG. 2A and FIGS. 4A to 4E.

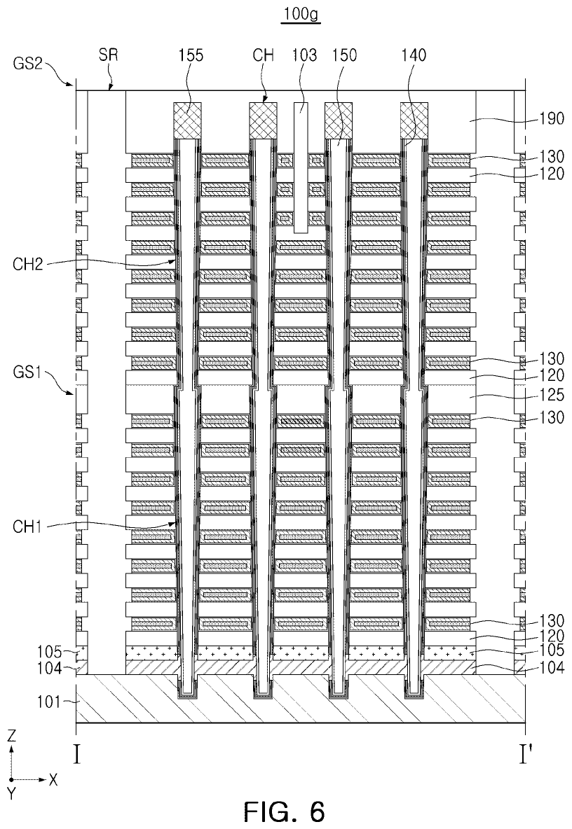

FIG. 6 is a schematic cross-sectional view of a semiconductor device according to example embodiments of the inventive concept.

Referring to FIG. 6, a semiconductor device 100g may include lower stack structures GS1 and upper stack structures GS2 in which stack structures of gate electrodes 130 are vertically stacked and may include lower channel structures CH1 and upper channel structures CH2. Such structures of the channel structures CH may be introduced to stably form the channel structures CH when the number of the gate electrodes 130 stacked is relatively large.

The channel structures CH may have a form in which the lower channel structures CH1 of the lower stack structure GS1 and the upper channel structures CH2 of the upper stack structure GS2 are connected, and may have a bent portion due to a difference in width of a region to be connected. A channel layer 140 and a channel insulating layer 150 may be connected to each other between the lower channel structure CH1 and the upper channel structure CH2. A channel pad 155 may be disposed only on the upper channel structure CH2. In example embodiments, the lower channel structure CH1 and the upper channel structure CH2 may include a channel pad 155, respectively, and, in such embodiments, the channel pad 155 of the lower channel structure CH1 may be connected to a channel layer 140 of the upper channel structure CH2. As in the embodiment of FIG. 2A, the semiconductor device 100g may include first and second conductive patterns 104 and 105, but embodiments are not limited thereto. For example, in the semiconductor device 100g, the channel structures CH may further include an epitaxial layer 107 disposed on lower ends of the channel structures CH, as in the embodiment of FIG. 5, instead of the first and second conductive patterns 104 and 105. An upper interlayer insulating layer 125 having a relatively thick thickness may be disposed on an uppermost portion of the lower stack structure GS1. Shapes of interlayer insulating layers 120 and a shape of the upper interlayer insulating layer 125 may be variously changed in different embodiments. For other configurations, with reference to FIGS. 1 to 3B, the description provided above may be equally applicable.

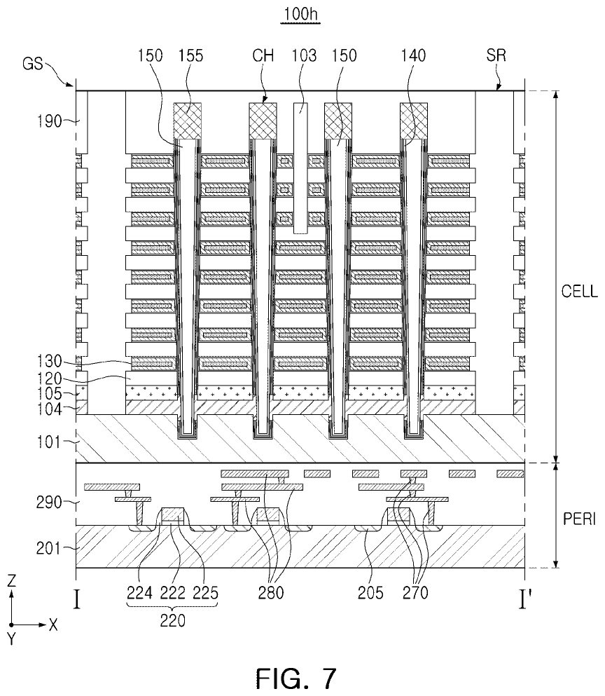

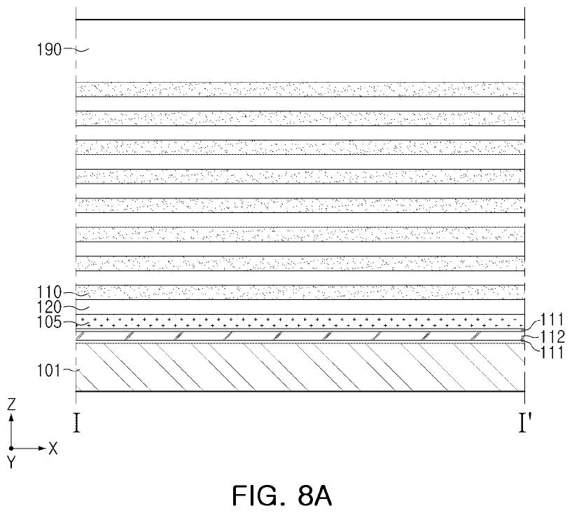

FIG. 7 is a schematic cross-sectional view of a semiconductor device according to example embodiments of the inventive concept.

Referring to FIG. 7, a semiconductor device 100h may include a memory cell region CELL and a peripheral circuit region PERI stacked in the vertical direction. The memory cell region CELL may be disposed above, i.e., in the Z direction, the peripheral circuit region PERI. For example, unlike the embodiments of FIG. 2a in which a peripheral circuit region PERI is not disposed on the substrate 101, in the semiconductor device 100h of FIG. 7, the memory cell region CELL and the peripheral circuit region PERI may be stacked in the vertical direction, i.e., Z direction. In some example embodiments, the cell region CELL may be also disposed below the peripheral circuit region PERI.

The peripheral circuit region PERI may include a base substrate 201, and circuit elements 220, circuit contact plugs 270, and circuit wiring lines 280, arranged on the base substrate 201.

The base substrate 201 may have an upper surface extending in the X and Y directions. In the base substrate 201, separate element separation layers may be formed to define an active region. Source/drain regions 205 including impurities may be disposed in a portion of the active region. The base substrate 201 may include a semiconductor material, such as one or more of a group IV semiconductor, a group III-V compound semiconductor, or a group II-VI compound semiconductor.

The circuit elements 220 may include horizontal transistors. Each of the circuit elements 220 may include a circuit gate dielectric layer 222, a spacer layer 224, and a circuit gate electrode 225. The source/drain regions 205 may be disposed in the base substrate 201 on both sides of the circuit gate electrode 225.

A peripheral region insulating layer 290 may be disposed on the circuit element 220 on the base substrate 201. The circuit contact plugs 270 may extend through the peripheral region insulating layer 290 and may be connected to the source/drain regions 205. The circuit contact plugs 270 may apply an electrical signal to the circuit element 220. In a region not illustrated, the circuit contact plugs 270 may be connected to the circuit gate electrode 225. The circuit wiring lines 280 may be connected to the circuit contact plugs 270 and may be provided as a plurality of layers.

In the semiconductor device 100h, after the peripheral circuit region PERI is first manufactured, a substrate 101 of the memory cell region CELL may be formed thereon to prepare the memory cell region CELL. The substrate 101 may have the same size as the base substrate 201 or may be formed smaller than the base substrate 201. The memory cell region CELL and the peripheral circuit region PERI may be connected to each other in a region not illustrated. For example, one end of a gate electrode 130 in the Y direction may be electrically connected to the circuit elements 220. In this way, an embodiment in which the memory cell region CELL and the peripheral circuit region PERI are vertically stacked may be applied to the embodiments of FIG. 2A and FIGS. 4A to 6. For other configurations, with reference to FIGS. 1 to 3B, the description described above may be equally applicable to the embodiments illustrated therein.

FIGS. 8A to 8G are schematic cross-sectional views illustrating a method of manufacturing a semiconductor device according to example embodiments of the inventive concept. FIGS. 8A to 8G illustrate cross-sectional views corresponding to FIG. 2A.

Referring to FIG. 8A, first and second source sacrificial layers 111 and 112 and a second conductive pattern 105 may be formed on a substrate 101, and horizontal sacrificial layers 110 and interlayer insulating layers 120 may be alternately stacked to form a stack structure.

First, the first and second source sacrificial layers 111 and 112 may include different materials and may be stacked on the substrate 101 to arrange the first source sacrificial layers 111 above and below the second source sacrificial layer 112. The first and second source sacrificial layers 111 and 112 may be layers to be replaced with the first conductive pattern 104 of FIG. 2A by a subsequent process. For example, the first source sacrificial layer 111 may be made of the same material as the interlayer insulating layers 120, and the second source sacrificial layer 112 may be made of the same material as the horizontal sacrificial layers 110. The second conductive pattern 105 may be deposited on the first and second source sacrificial layers 111 and 112.

Next, the horizontal sacrificial layers 110 and the interlayer insulating layers 120 may be alternately stacked on the second conductive pattern 105 to form a stack structure.

The horizontal sacrificial layers 110 may be layers to be replaced with gate electrodes 130 by a subsequent process. The horizontal sacrificial layers 110 may be formed of a material different from that of the interlayer insulating layers 120. For example, the interlayer insulating layer 120 may be formed of at least one of silicon oxide and/or silicon nitride, and the horizontal sacrificial layers 110 may be selected from silicon, silicon oxide, silicon carbide, and silicon nitride, but may be formed of a material different from that of the interlayer insulating layers 120. In some embodiments, the interlayer insulating layers 120 may not all have the same thickness. For example, a lowermost interlayer insulating layer 120 may be formed relatively thin, and an uppermost interlayer insulating layer 120 may be formed relatively thick. Thicknesses of the interlayer insulating layers 120 and the horizontal sacrificial layers 110, and the number of layers constituting them may be variously changed to be different from those illustrated in accordance with various embodiments of the inventive concept. A cell region insulating layer 190 may be formed on the top of the horizontal sacrificial layers 110 and interlayer insulating layers 120.

Referring to FIG. 8B, an upper insulating layer 103 may be formed, and channel structures CH extending through the stack structure may be formed.

First, the upper insulating layer 103 may be formed by removing a predetermined number of the horizontal sacrificial layers 110 and the interlayer insulating layers 120, starting from an uppermost portion of the stack structure, by using a separate mask layer. The upper insulating layer 103 may be formed by depositing an insulating material in a region from which the horizontal sacrificial layers 110 and the interlayer insulating layers 120 are removed. The upper insulating layer 103 may be made of a material having etch selectivity, together with the interlayer insulating layer 120, with respect to the horizontal sacrificial layers 110, and, for example, may be made of the same material as the interlayer insulating layer 120.

Next, channel holes may be formed to form the channel structures CH. The channel holes may be formed by anisotropically etching the stack structure and may be formed to have a hole shape. Due to a height of the stack structure, side walls of the channel holes may not be perpendicular to an upper surface of the substrate 101. The channel holes may be formed to recess a portion of the substrate 101.

Next, a channel layer 140, a channel insulating layer 150, and a channel pad 155 may be formed in each of the channel holes, and the tunneling layer 142, the charge storage layer 143, and the second blocking layer 144, as illustrated in FIG. 2B, may be formed to prepare channel structures CH. The channel layer 140, the tunneling layer 142, the charge storage layer 143, and the second blocking layer 144 may be disposed below the channel structures CH to extend into the substrate 101.

The channel layer 140, the tunneling layer 142, the charge storage layer 143, and the second blocking layer 144 may be formed to have a generally uniform thickness by using an atomic layer deposition (ALD) process or chemical vapor deposition (CVD) process. The channel insulating layer 150 may be formed to fill a space surrounded by the channel layer 140 and may be formed of an insulating material. The channel pad 155 may be made of a conductive material, for example, polycrystalline silicon.

Referring to FIG. 8C, the stack structures may be separated at predetermined intervals to form an opening OP extending therethrough, the first and second source sacrificial layers 111 and 112 may be removed by the opening OP, and a first conductive pattern 104 may be formed.

In some embodiments, before the opening OP is formed, an insulating layer may be additionally formed on the uppermost interlayer insulating layer 120 and the channel pad 155 to prevent breakage of the channel pad 155 and the channel layer 140 below the channel pad 155, and the like.

The opening OP may be prepared by forming a mask layer using a photolithography process, and anisotropically etching the stack structure of the horizontal sacrificial layers 110 and the interlayer insulating layers 120. The opening OP may be formed in a trench shape extending in the Y direction and may be formed in a region in which the separation insulating layer 185 of FIG. 2B is disposed.

In example embodiments, before the first and second source sacrificial layers 111 and 112 are removed, a spacer layer may be formed on a side wall of the opening OP to protect the horizontal sacrificial layers 110. After the second source sacrificial layer 112 is first removed by the opening OP, the first source sacrificial layers 111 may be removed. The first and second source sacrificial layers 111 and 112 may be removed by, for example, a wet etching process. During the removal process of the first source sacrificial layers 111, portions of the tunneling layer 142, the charge storage layer 143, and the second blocking layer 144, of FIG. 2B, exposed in a region from which the second source sacrificial layer 112 is removed, may be removed together. After forming the first conductive pattern 104 by depositing a conductive material in a region from which the first and second source sacrificial layers 111 and 112 are removed, the spacer layer may be removed. The first conductive pattern 104 may be in direct physical contact with the channel layer 140 in a region from which the tunneling layer 142, the charge storage layer 143, and the second blocking layer 144 are removed.

Referring to FIG. 8D, the horizontal sacrificial layers 110 exposed through the opening OP may be removed to form lateral openings LT.

The horizontal sacrificial layers 110 may be selectively removed from the interlayer insulating layers 120 using, for example, a wet etching process. Therefore, a plurality of lateral openings LT may be formed between the interlayer insulating layers 120, and a portion of side walls of the channel structures CH may be exposed through the lateral openings LT.

Referring to FIG. 8E, a first conductive layer 130a of a gate electrode 130 may be formed in the lateral openings LT.

Before the first conductive layer 130a is formed, a barrier metal layer 132 and a first blocking layer 134 may be formed in the lateral openings LT as illustrated in FIG. 2B, but embodiments of the inventive concept are not limited thereto.

The first conductive layer 130a may be formed by, for example, a CVD process or an ALD process. The first conductive layer 130a may be formed to have a substantially uniform thickness along side walls of the interlayer insulating layers 120 adjacent to each other in the vertical direction and the channel structures CH, but embodiments of the inventive concept are not limited thereto. The first conductive layer 130a may be formed to have a thickness that does not completely fill the lateral openings LT. Therefore, the first conductive layer 130a may have a lateral recess region LR formed to be concave toward the channel structure

CH.

Referring to FIG. 8F, a second conductive layer 130b may be formed on the first conductive layer 130a to prepare gate electrodes 130.

As illustrated in FIG. 8F, after depositing the first conductive layer 130a, the second conductive layer 130b may be sequentially stacked on the first conductive layer 130a without a separate etching process. After deposition of the first conductive layer 130a, because the second conductive layer 130b may be stacked without a separate etching process, invasion of etching gases by a subsequent etching process may be reduced or prevented in the lateral opening LT of FIG. 8E. The second conductive layer 130b may be formed by, for example, a CVD process or an ALD process. The second conductive layer 130b may include a metal or metal nitride that may at least partially fill the lateral openings LT between the interlayer insulating layers 120 adjacent to each other. For example, the second conductive layer 130b may include one or more of titanium (Ti), titanium nitride, tantalum (Ta), tantalum nitride, tungsten nitride, or the like.

Referring to FIGS. 8G and 2A together, materials constituting the gate electrodes 130 in the opening OP, formed on the side walls of the interlayer insulating layers 120 and the substrate 101, may be removed. Next, separation insulating layers 185 may be formed in the opening OP.

The first conductive layer 130a and the second conductive layer 130b, sequentially stacked in the openings OP, may be removed by an etching process, so that the gate electrode 130 remains only in the lateral openings LT. The etching process may be, for example, a wet etching process. Therefore, side surfaces of the gate electrodes 130 may be defined. For an electrical short between the gate electrodes 130 adjacent to each other in the vertical direction, the side surfaces of the gate electrodes 130 may be further inwardly recessed toward the channel structures CH, as compared to the side surfaces of the interlayer insulating layers 120.

The first conductive layer 130a and the second conductive layer 130b, formed in the openings OP, may be integrally removed by the etching process, to expose the side surfaces of the gate electrodes 130, e.g., a side surface of the first conductive layer 130a and a side surface of the second conductive layer 130b, to the openings OP. In this operation, because the barrier metal layer 132 formed in the openings OP may be also removed, the barrier metal layer 132 may have a side surface formed in the same position as, or in a position similar to, the side surface of the first conductive layer 130a and the side surface of the second conductive layer 130b. The side surface of the barrier metal layer 132 may be exposed to the openings OP.

When filling the openings LT of FIG. 8E by filling a space on the internal surface of the first conductive layer 130a with the second conductive layer 130b, because unnecessary etching of the conductive layer 130a by an etching gas in the etching process during this operation or remaining deposition gases may be reduced or prevented, the interlayer insulating layers 120 and the gate electrodes 130 may have a generally stable structure, and deterioration of electrical properties of the semiconductor device may be reduced or prevented.

After the material forming the gate electrodes 130 in the openings OP is removed so that the gate electrodes 130 remain only in the lateral openings LT, the gate electrodes 130 may have the shapes illustrated in FIG. 2B and FIGS. 4A to 4E. In an embodiment, as illustrated in FIG. 2B, side surfaces of the first conductive layer 130a and the second conductive layer 130b exposed to the openings OP may be flat surfaces. In another embodiment, as illustrated in FIGS. 4B to 4E, with regard to the first conductive layer 130a and the second conductive layer 130b, the first conductive layer 130a may be further removed in the etching process, as compared to the second conductive layer 130b, and the side surface of the second conductive layer 130b exposed to the openings OP may protrude further, as compared to the first conductive layer 130a exposed to the openings OP.

Next, separation insulating layers 185 may be formed in the openings OP. In an embodiment, as illustrated in FIG. 5, the separation insulating layers 185 may be formed in the form of spacers in the opening OP. For example, after depositing an insulating material, the insulating material formed on the substrate 101 may be removed from a lower portion of the opening OP to form the separation insulating layers 185.

According to an aspect of the present inventive concept, a semiconductor device having improved reliability may be provided by forming gate electrodes including a first conductive layer and a second conductive layer, sequentially stacked.

Various advantages and effects of the present inventive concept are not limited to those above described and can be more easily understood in the course of describing specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
gate electrodes stacked and spaced apart from each other in a first direction perpendicular to an upper surface of a substrate;
interlayer insulating layers alternately stacked with the gate electrodes on the substrate;
channel structures extending through the gate electrodes; and
a separation region extending through the gate electrodes in the first direction and extending in a second direction perpendicular to the first direction,
wherein each of the gate electrodes comprises a first conductive layer and a second conductive layer sequentially stacked, the second conductive layer including a metal nitride, and
wherein the first conductive layer and the second conductive layer are each in physical contact with the separation region.

2. The semiconductor device of claim 1, wherein the first conductive layer is on an upper surface, a lower surface, and a first side surface of the second conductive layer, and
a second side surface of the second conductive layer is in physical contact with the separation region.

3. The semiconductor device of claim 1, wherein the first conductive layer comprises tungsten (W), molybdenum (Mo), and/or copper (Cu).

4. The semiconductor device of claim 1, wherein the second conductive layer comprises titanium nitride, tantalum nitride, and/or tungsten nitride.

5. The semiconductor device of claim 1, wherein each of the gate electrodes further comprises a barrier metal layer between each of the interlayer insulating layers and the first conductive layer,
wherein the barrier metal layer is in physical contact with the separation region.

6. The semiconductor device of claim 1, wherein the second conductive layer has a region protruding toward the separation region relative to the first conductive layer.

7. The semiconductor device of claim 6, wherein each of the gate electrodes further comprises a barrier metal layer between each of the interlayer insulating layers and the first conductive layer,
wherein the barrier metal layer is in physical contact with the separation region, and the barrier metal layer further protrudes toward the separation region relative to a surface of the first conductive layer contacting the separation region.

8. The semiconductor device of claim 1, wherein the interlayer insulating layers protrude toward the separation region relative to the gate electrodes.

9. The semiconductor device of claim 1, wherein a thickness of the second conductive layer in the first direction is in a range of about 1% to about 30% of an interval between adjacent ones of the interlayer insulating layers in the first direction.

10. The semiconductor device of claim 1, wherein a thickness of the second conductive layer in the first direction is in a range of about 10% to about 20% of an interval between adjacent ones of the interlayer insulating layers in the first direction.

11. The semiconductor device of claim 1, wherein a thickness of the second conductive layer in the first direction is in a range of about 0.5 nm to about 8 nm.

12. The semiconductor device of claim 1, wherein a thickness of the second conductive layer in the first direction is in a range of about 1 nm to about 5 nm.

13. The semiconductor device of claim 1, wherein a thickness of the first conductive layer between an adjacent one of the interlayer insulating layers and the second conductive layer is substantially uniform in the first direction, and
a thickness of the second conductive layer is substantially uniform in the first direction.

14. A semiconductor device comprising:
gate electrodes stacked and spaced apart from each other in a first direction perpendicular to an upper surface of a substrate;
interlayer insulating layers alternately stacked with the gate electrodes on the substrate;
channel structures extending through the gate electrodes; and
a separation region extending through the gate electrodes in the first direction and extending in a second direction perpendicular to the first direction,
wherein each of the gate electrodes comprises a first conductive layer and a second conductive layer sequentially stacked, and
wherein a thickness of the second conductive layer in the first direction is in a range of about 1% to about 30% of an interval between adjacent ones of the interlayer insulating layers in the first direction.

15. The semiconductor device of claim 14, wherein the thickness of the second conductive layer in the first direction is in a range of about 10% to about 20% of the interval between the adjacent ones of the interlayer insulating layers in the first direction.

16. The semiconductor device of claim 14, wherein the second conductive layer comprises titanium (Ti), titanium nitride, tantalum (Ta), tantalum nitride, and/or tungsten nitride.

17. A semiconductor device comprising:
gate electrodes stacked and spaced apart from each other in a first direction perpendicular to an upper surface of a substrate;
interlayer insulating layers alternately stacked with the gate electrodes on the substrate;
channel structures extending through the gate electrodes; and
a separation region extending through the gate electrodes in the first direction and extending in a second direction perpendicular to the first direction,
wherein each of the gate electrodes comprises a first conductive layer and a second conductive layer on the first conductive layer, the gate electrodes being arranged on an internal surface bordered by adjacent ones of the interlayer insulating layers and one of the channel structures,
wherein the first conductive layer and the second conductive layer are each in physical contact with the separation region, and
wherein the first conductive layer comprises a first material having a first resistance, and the second conductive layer comprises a second material having a second resistance, greater than the first resistance, wherein the second material comprises nitrogen (N).

18. The semiconductor device of claim 17, wherein each of the gate electrodes comprises a central portion disposed around a center between adjacent ones of the interlayer insulating layers in the first direction, and an edge portion adjacent to the adjacent ones of the interlayer insulating layers relative to the central portion,
wherein the central portion has a longer length in a third direction, parallel to the upper surface of the substrate and perpendicular to the second direction relative to the edge portion.

19. The semiconductor device of claim 18, wherein the first conductive layer is in the edge portion of each of the gate electrodes, and the second conductive layer is in the central portion of each of the gate electrodes.

20. The semiconductor device of claim 18, wherein each of the gate electrodes further comprises a barrier metal layer between each of the interlayer insulating layers and the first conductive layer,
wherein the barrier metal layer protrudes toward the separation region relative to the first conductive layer.
